(19) United States
(12) Patent Application Publication
(10) Pub. No.: US 2024/0250140 A1
(43) Pub. Date: Jul. 25, 2024

(54) SEMICONDUCTOR ARCHITECTURE AND METHOD OF MANUFACTURING SEMICONDUCTOR ARCHITECTURE

(71) Applicant: HUAWEI TECHNOLOGIES CO., LTD., Shenzhen (CN)

(72) Inventor: Krishna Kumar Bhuwalka, Leuven (BE)

(21) Appl. No.: 18/531,030

(22) Filed: Dec. 6, 2023

Related U.S. Application Data
(63) Continuation of application No. PCT/EP2021/065305, filed on Jun. 8, 2021.

(51) Int. Cl. H01L 29/423; H01L 21/8238; H01L 27/092; H01L 29/06; H01L 29/66; H01L 29/775; H01L 29/786

(52) U.S. Cl. CPC H01L 29/42392; H01L 21/823807; H01L 21/823842; H01L 27/092; H01L 29/0665; H01L 29/66439; H01L 29/775; H01L 29/78696

(57) ABSTRACT

A semiconductor architecture includes a substrate, an n-type transistor, and a p-type transistor, each formed on the substrate. Each of the n-type transistor and the p-type transistor of the semiconductor architecture includes a plurality of finger sub-devices, and each finger sub-device of the plurality of finger sub-devices includes a plurality of stacked semiconductors. One or more of the finger sub-devices of the plurality of finger sub-devices for each of the n-type transistor and the p-type transistor is formed as a fork stack device including a dielectric barrier that extends down only one side of the stacked semiconductors.

### CROSS-REFERENCE TO RELATED APPLICATIONS

This application is a continuation of International Application No. PCT/EP2021/065305, filed on Jun. 8, 2021, the disclosure of which is hereby incorporated by reference in its entirety.

### FIELD

The present disclosure relates generally to the field of semiconductor devices and more specifically, to a semiconductor architecture and a method of manufacturing the semiconductor architecture.

### BACKGROUND

Generally, a semiconductor device is an electronic device that is based on electronic properties of a semiconductor material, such as silicon (Si), germanium (Ge) and the like, for its functioning. The semiconductor device is manufactured either as an individual device or as an integrated circuit (IC) device. A well-known semiconductor device is named as a metal oxide semiconductor field-effect transistor (MOSFET) that includes a drain terminal, a source terminal and a gate terminal. Another well-known semiconductor device with a partially improved performance, is named as fin field-effect transistor (FinFET) which is a multigate device. The FinFET device includes two or more gate terminals which lie on two, or three sides of a channel made by a source terminal and a drain terminal of the FinFET device, hence, the FinFET device manifests somewhat better electrical conduction properties in comparison to the known MOSFET device.

Currently, a gate all around FET (GAAFET) device is proposed as a replacement of the FinFET device or the FinFET based complementary metal oxide semiconductor (CMOS) logic devices (e.g., microprocessors, memory cells, etc.). A conventional GAAFET device is a multigate device having a channel made by a source terminal(s) and a drain terminal(s). The conventional GAAFET device is similar in concept with the FinFET device except that multiple gates surround the channel on all sides, which results into partly improved performance of the conventional GAAFET device over the FinFET device. The conventional GAAFET device includes one or more conventional N/P-type devices with multiple stacks of nanosheets (NS) or nanowires (NW) arranged on top of one another. The conventional GAAFET device with the multiple stacks of NS or NW which are either arranged in a single finger form or in a multiple finger form. The conventional GAAFET device with the multiple stacks of NS or NW arranged in the multiple finger form manifests partially improved electrical current. Moreover, the conventional GAAFET device with the multiple stacks of NS or NW with dielectric isolation is also available in the single finger form or in the multiple finger form, yet, lacks in electrical properties, such as threshold voltage and power performance trade off. Thereafter, a conventional fork-sheet (FS) device(s) with the multiple stacks of NS or NW arranged in the single finger form is proposed. The conventional FS device(s) with the multiple stacks of NS or NW arranged in the single finger form is a semi-gate all around architecture with n-type and p-type nanosheets separated by a dielectric isolation. The conventional FS device(s) with the multiple stacks of NS or NW arranged in the single finger form provides a partially improved speed-power performance (e.g., 10%) by partially reducing parasitic capacitance. In spite of the dielectric isolation, the conventional FS device(s) with the multiple stacks of NS or NW arranged in the single finger form is not preferred for high current and power performance trade off device(s). Thus, there exists a technical problem of low current and low power performance associated with the conventional semiconductor device(s).

Therefore, in light of the foregoing discussion, there exists a need to overcome the aforementioned draw backs associated with the conventional semiconductor devices.

### SUMMARY

The present disclosure provides a semiconductor architecture and a method of manufacturing the semiconductor architecture. The present disclosure provides a solution to the existing problem of low current and low power performance associated with the conventional semiconductor device(s). The present disclosure provides a solution that overcomes at least partially the problems encountered in the prior art and provides an improved semiconductor architecture and an improved method of manufacturing the semiconductor architecture that can be used for high power-performance trade-off devices as well as high current devices.

In one aspect, the present disclosure provides a semiconductor architecture comprising a substrate, and an n-type transistor and a p-type transistor, each formed on the substrate. Each of the n-type transistor and the p-type transistor includes a plurality of finger sub-devices, and each finger sub-device includes a plurality of stacked semiconductors. One or more of the finger sub-devices for each of the n-type transistor and the p-type transistor is formed as a fork stack device comprising a dielectric barrier which extends down one side only of the stacked semiconductors.

The disclosed semiconductor architecture presents a multi-stack multi-finger nanosheet and fork stack (or fork-sheet) semiconductor device. The semiconductor architecture along with the multi-finger architecture is beneficial for high-current devices and power-performance trade-off devices. Moreover, due to the dielectric barrier, each fork stack device of the semiconductor architecture reduces an effective parasitic capacitance (C_{eff}) and provides a better resistance-capacitance (R-C) trade-off. Besides, the plurality of stacked semiconductors enables the semiconductor architecture to have a compact size as well.

In an implementation form, three sides of each fork stack device are surrounded by a gate dielectric layer and an n-type metal gate layer or a p-type metal gate layer.

The gate dielectric layer and the n-type metal gate layer and the p-type metal gate layer of the semiconductor architecture are also beneficial in order to connect each fork stack device. This further results into high current and beneficially, the semiconductor architecture may be used in manufacturing high current devices in certain paths in a circuit.

In a further implementation form, each of the finger sub-devices which are not formed as fork stack devices are formed as gate-all-around devices, wherein all four sides are surrounded by a gate dielectric layer and an n-type metal gate layer or a p-type metal gate layer.

By virtue of using the gate-all-around (GAA) devices, the semiconductor architecture manifests the electrical properties of GAA semiconductor devices as well.

In a further implementation form, a finger sub-device of the n-type transistor and a finger sub-device of the p-type transistor share a dielectric barrier which extends between the n-type transistor and the p-type transistor.

By virtue of using the dielectric barrier, each fork stack device of the semiconductor architecture reduces an effective parasitic capacitance (C_{eff}) and provides a better resistance-capacitance (R-C) trade-off and hence, resulting into high performance of the semiconductor architecture.

In a further implementation form, a finger sub-device of the n-type transistor which is distal from the p-type transistor includes a dielectric barrier extending down a side of the stacked semiconductors which is distal from the p-type transistor: and a finger sub-device of the p-type transistor which is distal from the n-type transistor includes a dielectric barrier extending down a side of the stacked semiconductors which is distal from the n-type transistor.

This implementation form enables each of the n-type transistor and the p-type transistor to have two fork stack devices which further enables the semiconductor architecture to be used in high current and high-performance trade-off devices.

In a further implementation form, each of the n-type transistor and the p-type transistor includes two finger sub-devices which share a dielectric barrier extending between the respective finger sub-devices

It is advantageous to share the dielectric barrier extending between the respective finger sub-devices in order to obtain two fork stack devices for each of the n-type transistor and the p-type transistor.

In a further implementation form, each of the n-type transistor and the p-type transistor includes a total of two finger sub-devices.

It is advantageous to include the total of two finger sub-devices, because one finger sub-device of each of the n-type transistor and the p-type transistor can be used as the gate-all-around (GAA) devices, while another finger sub-device of each of the n-type transistor and the p-type transistor can be used as the fork stack device. Thus, the semiconductor architecture manifests electrical properties of both that is the GAA devices as well as the fork stack devices.

In a further implementation form, each of the finger sub-devices includes a total of three stacked semiconductors.

The three stacked semiconductors enable the semiconductor architecture to have a compact size.

In a further implementation form, the semiconductor architecture manufactured through a process of providing a substrate, forming the plurality of stacked semiconductors on the substrate, depositing a gate dielectric layer, etching a top and at least one side of each finger sub-device, leaving the dielectric barrier and depositing one or more metal gate layers.

The process used to manufacture the semiconductor architecture provides an identical multi-multi finger sub-device (or nanosheet devices) with a compact size that can be used for certain paths in a circuit.

In a further implementation form, depositing the one or more metal gate layers includes depositing an n-type metal gate layer, etching the n-type metal gate layer, and depositing a p-type metal gate layer.

The n-type metal gate layer and the p-type metal gate layer are used to connect each finger sub-device (or nanosheet devices) of the semiconductor architecture.

In another aspect, the present disclosure provides a method of manufacturing a semiconductor architecture, the method comprising providing a substrate, and forming a plurality of stacked semiconductors on the substrate to form an n-type transistor and a p-type transistor on the substrate, wherein each of the n-type transistor and the p-type transistor includes a plurality of finger sub-devices, and each finger sub-device includes a plurality of stacked semiconductors. The method further comprises depositing a dielectric layer, and etching a top and at least one side of each finger sub-device, leaving a dielectric barrier which extends down one side only of the stacked semiconductors. The method further comprises depositing one or more metal gate layers, such that one or more of the finger sub-devices for each of the n-type transistor and the p-type transistor is formed as a fork stack device comprising the dielectric barrier extending down one side only of the stacked semiconductors.

The method achieves all the advantages and effects of the semiconductor architecture of the present disclosure.

It is to be appreciated that all the aforementioned implementation forms can be combined.

It has to be noted that all devices, elements, circuitry, units and means described in the present application could be implemented in the software or hardware elements or any kind of combination thereof. All steps which are performed by the various entities described in the present application as well as the functionalities described to be performed by the various entities are intended to mean that the respective entity is adapted to or configured to perform the respective steps and functionalities. Even if, in the following description of specific embodiments, a specific functionality or step to be performed by external entities is not reflected in the description of a specific detailed element of that entity which performs that specific step or functionality, it should be clear for a skilled person that these methods and functionalities can be implemented in respective software or hardware elements, or any kind of combination thereof. It will be appreciated that features of the present disclosure are susceptible to being combined in various combinations without departing from the scope of the present disclosure as defined by the appended claims.

Additional aspects, advantages, and features of the present disclosure would be made apparent from the drawings and the detailed description of the illustrative implementations construed in conjunction with the appended claims that follow.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein. Moreover, those in the art will understand that the drawings are not to scale. Wherever possible, like elements have been indicated by identical numbers.

Embodiments of the present disclosure will now be described, by way of example only, with reference to the following diagrams wherein:

FIG. 1A is an illustration of a semiconductor architecture, in accordance with an embodiment of the present disclosure:

FIG. 1B is an illustration of a semiconductor architecture, in accordance with another embodiment of the present disclosure:

FIG. 1C is an illustration of a semiconductor architecture, in accordance with yet another embodiment of the present disclosure: and

FIG. 2 is a flowchart of a method of manufacturing a semiconductor architecture, in accordance with an embodiment of the present disclosure.

In the accompanying drawings, an underlined number is employed to represent an item over which the underlined number is positioned or an item to which the underlined number is adjacent. A non-underlined number relates to an item identified by a line linking the non-underlined number to the item. When a number is non-underlined and accompanied by an associated arrow; the non-underlined number is used to identify a general item at which the arrow is pointing.

### DETAILED DESCRIPTION

The following detailed description illustrates exemplary embodiments of the present disclosure and exemplary ways in which they can be implemented. Although some modes of carrying out the present disclosure have been disclosed, those skilled in the art would recognize that other embodiments for carrying out or practicing the present disclosure are also possible.

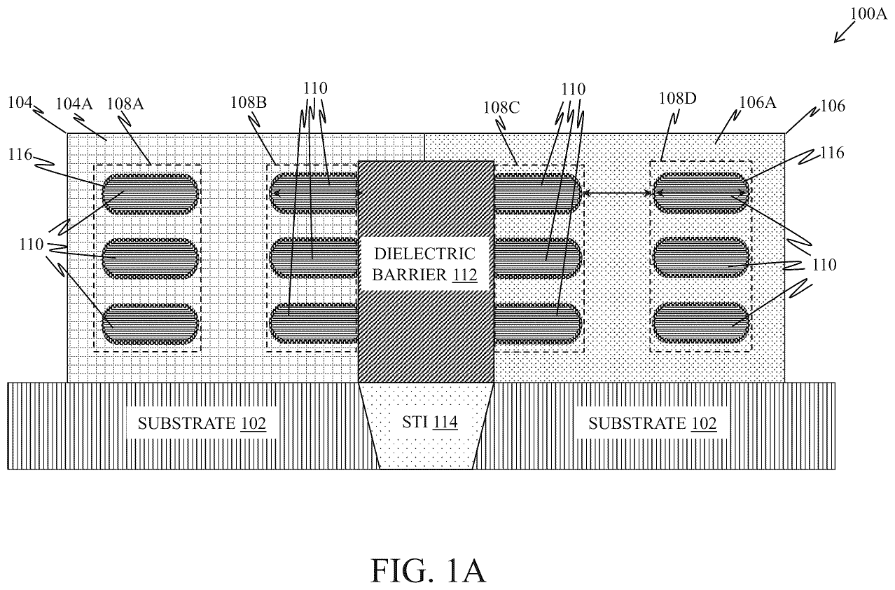

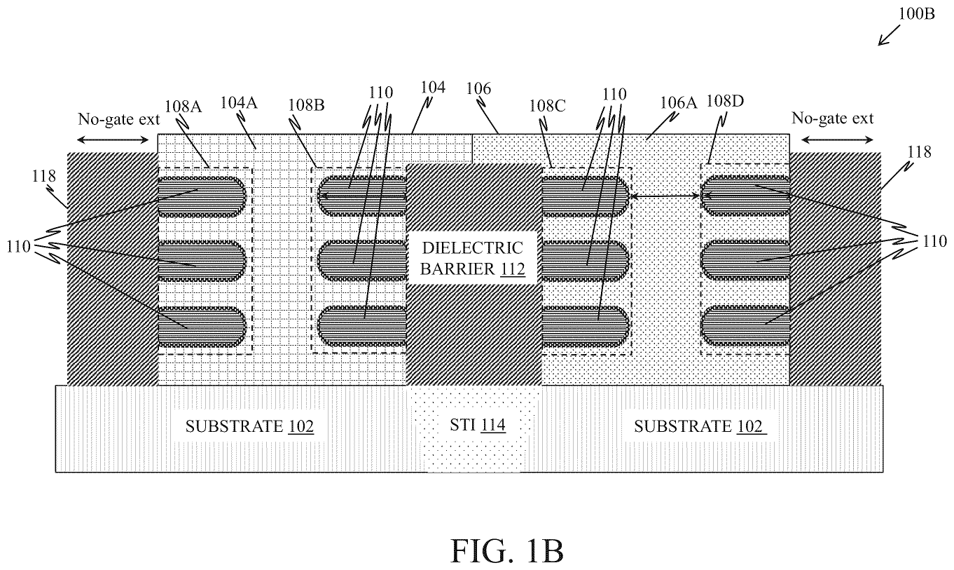

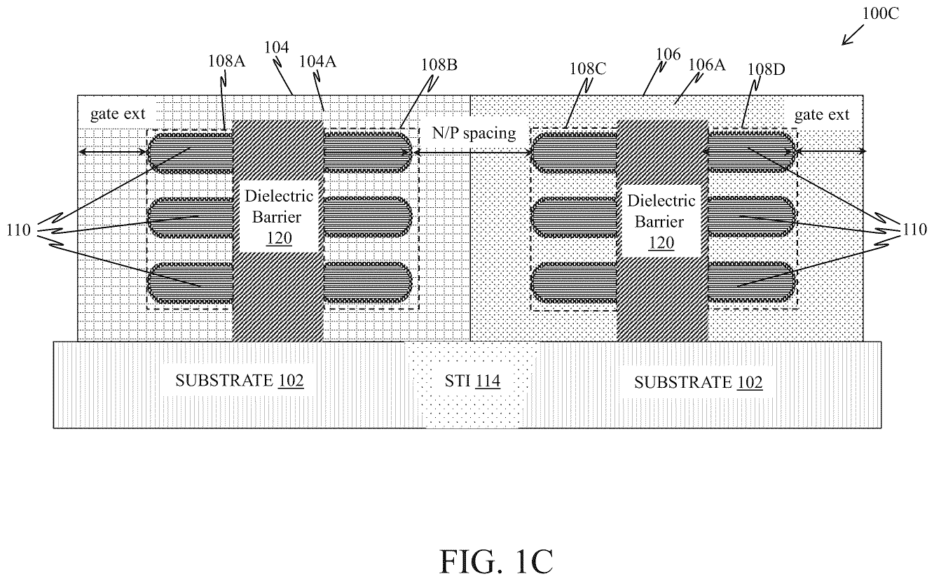

FIG. 1A is an illustration of a semiconductor architecture, in accordance with an embodiment of the present disclosure. With reference to FIG. 1A, there is shown a semiconductor architecture 100A. The semiconductor architecture 100A comprises a substrate 102, an n-type transistor 104, an n-type metal gate layer 104A, a p-type transistor 106, a p-type metal gate layer 106A, a plurality of finger sub-devices 108, such as a first finger sub-device 108A, a second finger sub-device 108B, a third finger sub-device 108C and a fourth finger sub-device 108D, a plurality of stacked semiconductors 110, a dielectric barrier 112. There is further shown a shallow trench isolation 114 and a gate dielectric layer 116. Each of the first finger sub-device 108A, the second finger sub-device 108B, the third finger sub-device 108C and the fourth finger sub-device 108D is represented by a dashed box, which is used for illustration purpose only and does not form a part of circuitry.

In one aspect, the present disclosure provides a semiconductor architecture 100A comprising:
a substrate 102: and
an n-type transistor 104 and a p-type transistor 106, each formed on the substrate 102;
wherein each of the n-type transistor 104 and the p-type transistor 106 includes a plurality of finger sub-devices 108, and each finger sub-device includes a plurality of stacked semiconductors 110; and
wherein one or more of the finger sub-devices (i.e., the plurality of finger sub-devices 108) for each of the n-type transistor 104 and the p-type transistor 106 is formed as a fork stack device comprising a dielectric barrier 112 which extends down one side only of the stacked semiconductors 110.

The semiconductor architecture 100A comprises the substrate 102. The semiconductor architecture 100A further comprises the n-type transistor 104 and the p-type transistor 106, each formed on the substrate 102. The semiconductor architecture 100A may also be referred to as a multiple-stack multiple-finger semiconductor device with nano-sheets (NS) and fork-sheets (FS) or multiple-stack multiple finger tri-gate nanosheet architecture. The fork-sheets (FS) corresponds to a three-gate horizontal device and enables the semiconductor architecture 100A to have a reduced cell size and reduced parasitic capacitance as well. The semiconductor architecture 100A may be used in complementary metal-oxide-semiconductor (CMOS) based integrated circuits, electronic devices, and the like.

The substrate 102 may also be referred as a single wafer or a chip. The substrate 102 is made up of a semiconductor material such as, silicon (Si) or germanium (Ge) and the like. In the semiconductor material of the substrate 102, a n-type dopant is added. Therefore, the substrate 102 may also be referred as a n-type semiconductor or n-well semiconductor. Generally, a n-type semiconductor is one in which majority charge carriers are electrons. Examples of the n-type semiconductor are, but not limited to, phosphorus (P), arsenic (As), antimony (Sb), and the like. The substrate 102 may also have an isolation property. In another embodiment, the substrate 102 may have p-type doping hence, may be referred as a p-type semiconductor. Generally, a p-type semiconductor is one in which majority charge carriers are holes. Examples of the p-type semiconductor are, but not limited to, boron (B), indium (In), gallium (Ga), aluminium (Al), and the like.

Each of the n-type transistor 104 and the p-type transistor 106 is a field effect transistor (FET). More specifically, the n-type transistor 104 is a n-type FET (N-FET) and the p-type transistor 106 is a p-type FET (P-FET). Each of the n-type transistor 104 (i.e., N-FET) and the p-type transistor 106 (i.e., P-FET) includes three terminals, namely, a gate terminal, a source terminal and a drain terminal. The n-type transistor 104 (i.e., N-FET) acts as a close circuit when the gate terminal of the n-type transistor 104 is supplied with a high voltage and acts as an open circuit when the gate terminal of the n-type transistor 104 is supplied with a low voltage. However, on the opposite side, the p-type transistor 106 (i.e., P-FET) acts as an open circuit when the gate terminal of the p-type transistor 106 is supplied with a high voltage and acts as a close circuit when the gate terminal of the p-type transistor 106 is supplied with a low voltage. Each of the n-type transistor 104 (i.e., N-FET) and the p-type transistor 106 (i.e., P-FET) is formed on the substrate 102.

The plurality of finger sub-devices 108, such as the first finger sub-device 108A, the second finger sub-device 108B, the third finger sub-device 108C and the fourth finger sub-device 108D, may also be referred to as nanosheet semiconductor devices. The plurality of finger sub-devices 108 is made of the plurality of stacked semiconductors 110.

The dielectric barrier 112 is an insulating polymer film, and the shallow trench isolation (STI) 114 is also known as the box isolation technique. In an example, the shallow trench isolation 114 prevents electric current leakage between adjacent components of the semiconductor architecture 100A.

The gate dielectric layer 116 is an insulating layer that can be polarized by an applied electric field.

Each of the n-type transistor 104 and the p-type transistor 106 includes the plurality of finger sub-devices 108, and each finger sub-device includes the plurality of stacked semiconductors 110. One or more of the finger sub-devices (i.e., the plurality of finger sub-devices 108) for each of the n-type transistor 104 and the p-type transistor 106 is formed as a fork stack device comprising the dielectric barrier 112 which extends down one side only of the stacked semiconductors 110. The plurality of finger sub-devices 108 includes, such as the first finger sub-device 108A, the second finger sub-device 108B, the third finger sub-device 108C and the fourth finger sub-device 108D. The plurality of finger sub-devices 108 may also be referred to as one or more finger sub-devices. The n-type transistor 104 (i.e., N-FET) includes the first finger sub-device 108A and the second finger sub-device 108B. Similarly, the p-type transistor 106 (i.e., P-FET) includes the third finger sub-device 108C and the fourth finger sub-device 108D. Each of the plurality of finger sub-devices 108 further includes the plurality of stacked semiconductors 110 (e.g., 3 stacked semiconductors) which are vertically arranged semiconductors. The plurality of stacked semiconductors 110 corresponds to either nanosheets (NS) or nanowires (NW) stacked on top of each other. Moreover, one or more of the finger sub-devices (i.e., the plurality of finger sub-devices 108) of the n-type transistor 104 and the p-type transistor 106 is formed as the fork-stack (or fork-sheet. FS) device. For example, the second finger sub-device 108B of the n-type transistor 104 and the third finger sub-device 108C of the p-type transistor 106 is formed as the fork-stack (FS) device. The fork-stack (FS) device may be defined as a three-gate horizontal device which manifests a reduced cell size and a reduced parasitic capacitance. The second finger sub-device 108B of the n-type transistor 104 and the third finger sub-device 108C of the p-type transistor 106 further comprise the dielectric barrier 112 arranged between the second finger sub-device 108B and the third finger sub-device 108C. The dielectric barrier 112 extends down one side only of the stacked semiconductors 110. For example, the dielectric barrier 112 extends down one side only of the stacked semiconductors 110 of the second finger sub-device 108B and the third finger sub-device 108C. Therefore, the semiconductor architecture 100A along with the fork stack device (or multi-finger architecture) is beneficial for high-current devices and power-performance trade-off devices. Moreover, due to the dielectric barrier 112, an effective parasitic capacitance (C_{eff}) is reduced for the fork stack device of the semiconductor architecture 100A, such as the second finger sub-device 108B of the n-type transistor 104 and the third finger sub-device 108C of the p-type transistor 106. Further, the semiconductor architecture 100A provides a better resistance-capacitance (R-C) trade-off.

In accordance with an embodiment, each of the n-type transistor 104 and the p-type transistor 106 includes a total of two finger sub-devices. In other words, the n-type transistor 104 includes the two finger sub-devices, namely, the first finger sub-device 108A and the second finger sub-device 108B. Similarly, the p-type transistor 106 includes the two finger sub-devices, namely, the third finger sub-device 108C and the fourth finger sub-device 108D.

In accordance with an embodiment, each of the finger sub-devices (i.e., the plurality of finger sub-devices 108) includes a total of three stacked semiconductors. In the semiconductor architecture 100A, each of the finger sub-devices such as the first finger sub-device 108A, the second finger sub-device 108B, the third finger sub-device 108C and the fourth finger sub-device 108D includes the total of three stacked semiconductors (i.e., the plurality of stacked semiconductors 110). For example, the first finger sub-device 108A includes three nanosheets (NS) or nanowires (NW) arranged on top of each other. Similarly, each of the second finger sub-device 108B, the third finger sub-device 108C and the fourth finger sub-device 108D includes three stacked nanosheets (NS) or nanowires (NW).

In accordance with an embodiment, three sides of each fork stack device are surrounded by the gate dielectric layer 116 and the n-type metal gate layer 104A or the p-type metal gate layer 106A. As the dielectric barrier 112 extends down one side only of the stacked semiconductors 110 of each fork stack device, therefore, the three sides of each fork stack device are surrounded by the gate dielectric layer 116 and the n-type metal gate layer 104A or the p-type metal gate layer 106A. For example, the three sides of the second finger sub-device 108B of the n-type transistor 104 which acts as the fork-stack device is surrounded by the gate dielectric layer 116 and the n-type metal gate layer 104A. The n-type metal gate layer 104A is comprised by the n-type transistor 104. Similarly, the three sides of the third finger sub-device 108C of the p-type transistor 106 which acts as the fork-stack device is surrounded by the gate dielectric layer 116 and the p-type metal gate layer 106A. The p-type metal gate layer 106A is comprised by the p-type transistor 106. Beneficially, in comparison with a conventional fork stack semiconductor device, the gate dielectric layer 116, the n-type metal gate layer 104A and the p-type metal gate layer 106A are used to connect the second finger sub-device 108B of the n-type transistor 104 and the third finger sub-device 108C of the p-type transistor 106.

In accordance with an embodiment, each of the finger sub-devices (i.e., the plurality of finger sub-devices 108) which are not formed as fork stack devices are formed as gate-all-around devices, wherein all four sides are surrounded by the gate dielectric layer 116 and the n-type metal gate layer 104A or the p-type metal gate layer 106A. For example, the first finger sub-device 108A of the n-type transistor 104 and the fourth finger sub-device 108D of the p-type transistor 106 are not formed as fork stack devices and formed as gate-all-around (GAA) devices. Therefore, all four sides of the first finger sub-device 108A are surrounded by the gate dielectric layer 116 and the n-type metal gate layer 104A. Similarly, all four sides of the fourth finger sub-device 108D are surrounded by the gate dielectric layer 116 and the p-type metal gate layer 106A. In this way, the semiconductor architecture 100A manifests the electrical properties of the GAA semiconductor devices.

In accordance with an embodiment, a finger sub-device of the n-type transistor 104 and a finger sub-device of the p-type transistor 106 share the dielectric barrier 112 which extends between the n-type transistor 104 and the p-type transistor 106. As the dielectric barrier 112 is shared by the second finger sub-device 108B of the n-type transistor 104 and the third finger sub-device 108C of the p-type transistor 106. Therefore, a part of the dielectric barrier 112 extends towards the n-type transistor 104, while the other part of the dielectric barrier 112 extends towards the p-type transistor 106. In this way, the dielectric barrier 112 extends between the n-type transistor 104 and the p-type transistor 106.

In accordance with an embodiment, a finger sub-device of the n-type transistor 104 which is distal from the p-type transistor 106 includes a dielectric barrier extending down a side of the stacked semiconductors 110 which is distal from the p-type transistor 106. A finger sub-device of the p-type transistor 106 which is distal from the n-type transistor 104 includes a dielectric barrier extending down a side of the stacked semiconductors 110 which is distal from the n-type transistor 104. For example, the first finger sub-device 108A of the n-type transistor 104 is distal from the p-type transistor 106. The first finger sub-device 108A includes the dielectric barrier which extends down the side of the stacked semiconductors 110 of the first finger sub-device 108A and distal from the p-type transistor 106. Similarly, the fourth finger sub-device 108D of the p-type transistor 106 is distal from the n-type transistor 104. The fourth finger sub-device 108D includes the dielectric barrier which extends down the side of the stacked semiconductors 110 of the fourth finger sub-device 108D and distal from the n-type transistor 104. This is further described in more detail, for example, in FIG. 1B.

In accordance with an embodiment, each of the n-type transistor 104 and the p-type transistor 106 includes two finger sub-devices which share a dielectric barrier extending between the respective finger sub-devices. In other words, the n-type transistor 104 includes the two finger sub-devices, such as the first finger sub-device 108A and the second finger sub-device 108B, which share the dielectric barrier among each other. In this way, the first finger sub-device 108A and the second finger sub-device 108B act as the fork-stack devices for the n-type transistor 104. Similarly, the p-type transistor 106 includes the two finger sub-devices, such as the third finger sub-device 108C and the fourth finger sub-device 108D, which share the dielectric barrier among each other. In this way, the third finger sub-device 108C and the fourth finger sub-device 108D act as the fork-stack devices for the p-type transistor 106. Therefore, each of the n-type transistor 104 and the p-type transistor 106 includes two fork-stack devices. This is further described in more detail, for example, in FIG. 1C.

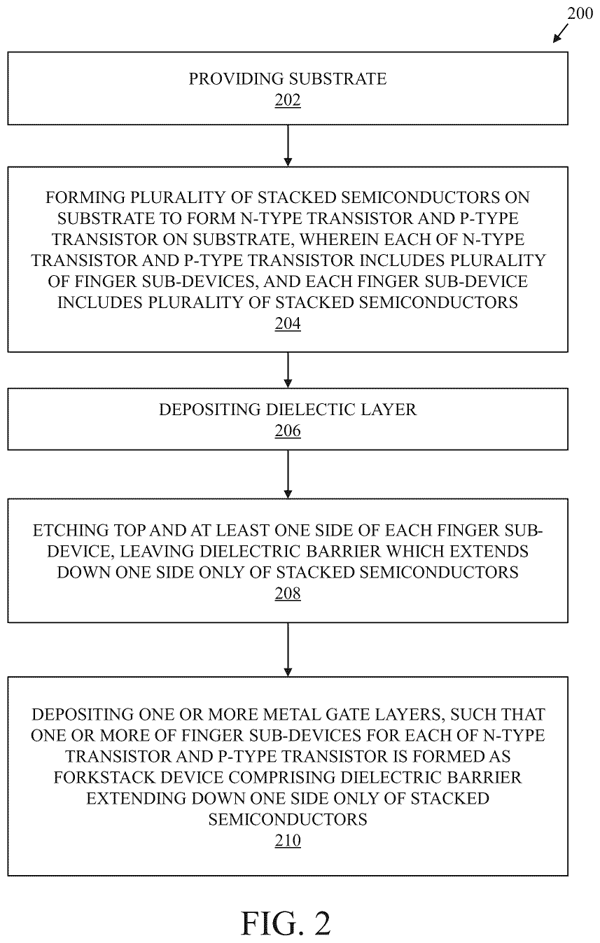

In accordance with an embodiment, the semiconductor architecture 100A manufactured through a process of providing the substrate 102. The process further comprises forming the plurality of stacked semiconductors 110 on the substrate 102 and depositing the gate dielectric layer 116. The process further comprises etching a top and at least one side of each finger sub-device, leaving the dielectric barrier 112, and depositing one or more metal gate layers. In other words, the process of manufacturing the semiconductor architecture 100A starts with substrate 102, which acts as the base of the semiconductor architecture 100A. Thereafter, the plurality of stacked semiconductors 110 is formed on the substrate 102 to form the plurality of finger sub-devices 108, such as the first finger sub-device 108A, the second finger sub-device 108B, the third finger sub-device 108C and the fourth finger sub-device 108D. Moreover, the gate dielectric layer 116 is deposited over the plurality of stacked semiconductors 110, which acts as an insulating layer. Thereafter, the top and at least one side of each finger sub-device is etched, leaving the dielectric barrier 112. For example, in the semiconductor architecture 100A, one side of the second finger sub-device 108B of the n-type transistor 104 and the third finger sub-device 108C of the p-type transistor 106 is etched and the dielectric barrier 112 is deposited between the two. Thereafter, the n-type metal gate layer 104A is deposited in the n-type transistor 104 and the p-type metal gate layer 106A is deposited in the p-type transistor 106. The process is further described in more detail, for example, in FIG. 2.

In accordance with an embodiment, depositing the one or more metal gate layers includes depositing the n-type metal gate layer 104A, etching the n-type metal gate layer 104A, and depositing the p-type metal gate layer 106A. The process further comprises deposition of the one or more metal gate layers which starts from the deposition of the n-type metal gate layer 104A all over the substrate 102. Thereafter, the n-type metal gate layer 104A is etched from a certain portion of the substrate 102. Thereafter, on the etched side of the substrate 102 the p-type metal gate layer 106A is deposited. As a result, the two metal gate layers are formed on the substrate 102, such as the n-type metal gate layer 104A and the p-type metal gate layer 106A. Further, the n-type metal gate layer 104A and the p-type metal gate layer 106A are used to connect the plurality of finger sub-devices 108.

Thus, the semiconductor architecture 100A presents a multi-stack multi-finger nanosheet and fork stack (or fork-sheet) semiconductor device. The semiconductor architecture 100A along with the multi-finger architecture is beneficial for high-current devices and power-performance trade-off devices. Moreover, due to the dielectric barrier 112, each fork stack device of the semiconductor architecture 100A reduces an effective parasitic capacitance (C_{eff}) and provides a better resistance-capacitance (R-C) trade-off. The gate dielectric layer 116 and the n-type metal gate layer 104A and the p-type metal gate layer 106A of the semiconductor architecture 100A are also beneficial in order to connect each fork stack device, such as the second finger sub-device 108B and the third finger sub-device 108C. This further results into high current and beneficially, the semiconductor architecture 100A may be used in manufacturing high current devices in certain paths in a circuit. Besides, the stacked semiconductors 110 enables the semiconductor architecture 100A to have a compact size as well.

FIG. 1B is an illustration of a semiconductor architecture, in accordance with another embodiment of the present disclosure. FIG. 1B is described in conjunction with elements from FIG. 1A. With reference to FIG. 1B, there is shown a semiconductor architecture 100B that includes a dielectric barrier 118.

The semiconductor architecture 100B is similar to the semiconductor architecture 100A (of FIG. 1A) except a difference. The difference is that the first finger sub-device 108A of the n-type transistor 104 includes the dielectric barrier 118 which extends down one side only of the stacked semiconductors 110 of the first finger sub-device 108A. Additionally, the fourth finger sub-device 108D of the p-type transistor 106 includes the dielectric barrier 118 which extends down one side only of the stacked semiconductors 110 of the fourth finger sub-device 108D. The dielectric barrier 118 corresponds to the dielectric barrier 112. In this way, in addition to the dielectric barrier 112 which extends down one side only of the stacked semiconductors 110 of the second finger sub-device 108B and the third finger sub-device 108C, the semiconductor architecture 100B includes the dielectric barrier 118 arranged with the first finger sub-device 108A and the fourth finger sub-device 108D. Thus, the first finger sub-device 108A and the fourth finger sub-device 108D also act as the fork-stack devices. Therefore, each of the n-type transistor 104 and the p-type transistor 106 of the semiconductor architecture 100B includes two fork-stack devices. For example, the n-type transistor 104 includes the first finger sub-device 108A and the second finger sub-device 108B as the fork-stack devices. Similarly, the p-type transistor 106 includes the third finger sub-device 108C and the fourth finger sub-device 108D as the fork-stack devices.

In accordance with an embodiment, a finger sub-device (i.e., the first finger sub-device 108A) of the n-type transistor 104 which is distal from the p-type transistor 106 includes the dielectric barrier 118 extending down a side of the stacked semiconductors 110 which is distal from the p-type transistor 106. A finger sub-device (i.e., the fourth finger sub-device 108D) of the p-type transistor 106 which is distal from the n-type transistor 104 includes the dielectric barrier 118 extending down a side of the stacked semiconductors 110 which is distal from the n-type transistor 104. As the first finger sub-device 108A of the n-type transistor 104 is distal from the p-type transistor 106, therefore, a side of the stacked semiconductors 110 of the first finger sub-device 108A is also distal from the p-type transistor 106. There is further shown the dielectric barrier 118 which extends down the side of the stacked semiconductors 110 of the first finger sub-device 108A which is distal from the p-type transistor 106. Similarly, the fourth finger sub-device 108D of the p-type transistor 106 is distal from the n-type transistor 104, therefore a side of the stacked semiconductors 110 of the fourth finger sub-device 108D is also distal from the n-type transistor 104. There is further shown the dielectric barrier 118 which extends down the side of the stacked semiconductors 110 of the fourth finger sub-device 108D which is distal from the n-type transistor 104. Moreover, no gate extension exists for the first finger sub-device 108A of the n-type transistor 104 and the fourth finger sub-device 108D of the p-type transistor 106.

The semiconductor architecture 100B includes dielectric isolation alternatively between the plurality of finger sub-devices 108 and hence, each of the n-type transistor 104 and the p-type transistor 106 of the semiconductor architecture 100B includes two fork-stack devices.

FIG. 1C is an illustration of a semiconductor architecture, in accordance with yet another embodiment of the present disclosure. FIG. 1C is described in conjunction with elements from FIGS. 1A, and 1B. With reference to FIG. 1C, there is shown a semiconductor architecture 100C that includes a dielectric barrier 120.

In accordance with an embodiment, each of the n-type transistor 104 and the p-type transistor 106 includes two finger sub-devices which share the dielectric barrier 120 extending between the respective finger sub-devices. The semiconductor architecture 100C is similar to the semiconductor architecture 100A (of FIG. 1A) except a difference. The difference is that the first finger sub-device 108A and the second finger sub-device 108B of the n-type transistor 104 includes the dielectric barrier 120 which extends down one side only of the stacked semiconductors 110 of the first finger sub-device 108A and the second finger sub-device 108B. Similarly, the third finger sub-device 108C and the fourth finger sub-device 108D of the p-type transistor 106 includes the dielectric barrier 120 which extends down one side only of the stacked semiconductors 110 of the third finger sub-device 108C and the fourth finger sub-device 108D. In this way, the dielectric barrier 120 extends between the respective finger sub-devices, such as between the first finger sub-device 108A and the second finger sub-device 108B, and between the third finger sub-device 108C and the fourth finger sub-device 108D, but not at the separation of the n-type transistor 104 and the p-type transistor 106. In the semiconductor architecture 100C, gate extension exists for the first finger sub-device 108A of the n-type transistor 104 and the fourth finger sub-device 108D of the p-type transistor 106.

The semiconductor architecture 100C includes dielectric isolation in between the plurality of finger sub-devices 108 and hence, the semiconductor architecture 100C includes two finger fork-stack devices.

FIG. 2 is a flowchart of a method of manufacturing a semiconductor architecture, in accordance with an embodiment of the present disclosure. FIG. 2 is described in conjunction with elements from FIGS. 1A, 1B, and 1C. With reference to FIG. 2, there is shown a method 200 of manufacturing the semiconductor architecture 100A (of FIG. 1A). The method 200 comprises steps 202 to 210.

In another aspect, the present disclosure provides a method 200 of manufacturing the semiconductor architecture 100A, the method 200 comprising:
providing the substrate 102;
forming the plurality of stacked semiconductors 110 on the substrate 102 to form the n-type transistor 104 and the p-type transistor 106 on the substrate 102, wherein each of the n-type transistor 104 and the p-type transistor 106 includes the plurality of finger sub-devices 108, and each finger sub-device includes the plurality of stacked semiconductors 110;
depositing the gate dielectric layer 116;
etching a top and at least one side of each finger sub-device, leaving the dielectric barrier 112 which extends down one side only of the stacked semiconductors 110; and
depositing one or more metal gate layers, such that one or more of the finger sub-devices for each of the n-type transistor 104 and the p-type transistor 106 is formed as a fork stack device comprising the dielectric barrier 112 extending down one side only of the stacked semiconductors 110.

At step 202, the method 200 comprises, providing the substrate 102. The method 200 of manufacturing the semiconductor architecture 100A initiates with providing the substrate 102.

At step 204, the method 200 further comprises forming the plurality of stacked semiconductors 110 on the substrate 102 to form the n-type transistor 104 and the p-type transistor 106 on the substrate 102, wherein each of the n-type transistor 104 and the p-type transistor 106 includes the plurality of finger sub-devices 108, and each finger sub-device includes the plurality of stacked semiconductors 110. The plurality of stacked semiconductors 110 is formed on the substrate 102 resulting in the formation of the n-type transistor 104 and the p-type transistor 106. Each of the n-type transistor 104 and the p-type transistor 106 includes the plurality of finger sub-devices 108. For example, the n-type transistor 104 comprises the first finger sub-device 108A and the second finger sub-device 108B. Similarly, the p-type transistor 106 comprises the third finger sub-device 108C and the fourth finger sub-device 108D. Furthermore, each of the plurality of finger sub-devices 108 includes the plurality of stacked semiconductors 110.

At step 206, the method 200 further comprises depositing the gate dielectric layer 116. The gate dielectric layer 116 is deposited on each semiconductor of the plurality of stacked semiconductors 110 of each of the plurality of finger sub-devices 108. The gate dielectric layer 116 acts as an insulation layer around each of the plurality of stacked semiconductors 110.

At step 208, the method 200 further comprises etching a top and at least one side of each finger sub-device, leaving the dielectric barrier 112 which extends down one side only of the stacked semiconductors 110. The top and at least one side of each finger sub-device is etched, leaving the dielectric barrier 112. For example, in the semiconductor architecture 100A, one side of the second finger sub-device 108B of the n-type transistor 104 and the third finger sub-device 108C of the p-type transistor 106 is etched and the dielectric barrier 112 is deposited between the two which extends down one side (i.e., the etched side) only of the stacked semiconductors 110.

At step 210, the method 200 further comprises depositing one or more metal gate layers, such that one or more of the finger sub-devices for each of the n-type transistor 104 and the p-type transistor 106 is formed as a fork stack device comprising the dielectric barrier 112 extending down one side only of the stacked semiconductors 110. After deposition of the dielectric barrier 112, the one or more metal gate layers are deposited on the substrate 102. For example, the n-type metal gate layer 104A is deposited in the n-type transistor 104 and the p-type metal gate layer 106A is deposited in the p-type transistor 106. Due to the presence of the dielectric barrier 112 between the second finger sub-device 108B of the n-type transistor 104 and the third finger sub-device 108C of the p-type transistor 106, the second finger sub-device 108B and the third finger sub-device 108C act as the fork-stack device.

In accordance with an embodiment, the etching and depositing steps are configured to surround three sides of each fork stack device with the gate dielectric layer 116 and the n-type metal gate layer 104A or the p-type metal gate layer 106A. The method 200 further comprises surrounding the three sides of each fork stack device by the gate dielectric layer 116 and the n-type metal gate layer 104A or the p-type metal gate layer 106A. For example, the three sides of the second finger sub-device 108B (or the fork stack device) are surrounded by the gate dielectric layer 116 and the n-type metal gate layer 104A. Similarly, the three sides of the third finger sub-device 108C (or the fork stack device) are surrounded by the gate dielectric layer 116 and the p-type metal gate layer 106A, as shown in the FIG. 1A. Beneficially in comparison with conventional approaches of manufacturing conventional semiconductor architectures, the method 200 comprises using the gate dielectric layer 116, the n-type metal gate layer 104A and the p-type metal gate layer 106A for connecting the second finger sub-device 108B (or the fork stack device) of the n-type transistor 104 with the third finger sub-device 108C (or the fork stack device) of the p-type transistor 106 with each other.

In accordance with an embodiment, the etching and depositing steps are configured to form the finger sub-devices which are not formed as fork stack devices as gate-all-around devices, wherein all four sides are surrounded by the gate dielectric layer 116 and the n-type metal gate layer 104A or the p-type metal gate layer 106A. The steps of etching and depositing are further configured to form the first finger sub-device 108A and the fourth finger sub-device 108D as gate-all-around (GAA) devices. Moreover, all four sides of the first finger sub-device 108A is surrounded by the gate dielectric layer 116 and the n-type metal gate layer 104A. Similarly, all four sides of the fourth finger sub-device 108D are surrounded by the gate dielectric layer 116 and the p-type metal gate layer 106A. Therefore, the semiconductor architecture 100A manifests the electrical properties of the GAA semiconductor devices.

In accordance with an embodiment, the etching of a finger sub-device of the n-type transistor 104 and a finger sub-device of the p-type transistor 106 forms the dielectric barrier 112 which extends between the n-type transistor 104 and the p-type transistor 106. The etching steps further include the formation of the dielectric barrier 112 between the second finger sub-device 108B of the n-type transistor 104 and the third finger sub-device 108C of the p-type transistor 106. Therefore, a part of the dielectric barrier 112 extends towards the n-type transistor 104, while another part of the dielectric barrier 112 extends towards the p-type transistor 106. In this way, the dielectric barrier 112 is formed between spacing of the n-type transistor 104 and the p-type transistor 106.

In accordance with an embodiment, the etching of a finger sub-device of the n-type transistor 104 which is distal from the p-type transistor 106 forms a dielectric barrier extending down a side of the stacked semiconductors 110 which is distal from the p-type transistor 106; and the etching of a finger sub-device of the p-type transistor 106 which is distal from the n-type transistor 104 forms a dielectric barrier extending down a side of the stacked semiconductors 110 which is distal from the n-type transistor 104. For example, in the semiconductor architecture 100B (of FIG. 1B) the first finger sub-device 108A of the n-type transistor 104 includes the dielectric barrier 118 which extends down one side only of the stacked semiconductors 110 of the first finger sub-device 108A. Additionally, the fourth finger sub-device 108D of the p-type transistor 106 includes the dielectric barrier 118 which extends down one side only of the stacked semiconductors 110 of the fourth finger sub-device 108D. The dielectric barrier 118 corresponds to the dielectric barrier 112 of FIG. 1A. In this way, in addition to the dielectric barrier 112 which extends down one side only of the stacked semiconductors 110 of the second finger sub-device 108B and the third finger sub-device 108C, the semiconductor architecture 100B includes the dielectric barrier 118 arranged with the first finger sub-device 108A and the fourth finger sub-device 108D. Thus, the first finger sub-device 108A and the fourth finger sub-device 108D also act as the fork-stack devices. Therefore, each of the n-type transistor 104 and the p-type transistor 106 of the semiconductor architecture 100B includes two fork-stack devices. For example, the n-type transistor 104 includes the first finger sub-device 108A and the second finger sub-device 108B as the fork-stack devices. Similarly, the p-type transistor 106 includes the third finger sub-device 108C and the fourth finger sub-device 108D as the fork-stack devices.

In accordance with an embodiment, each of the n-type transistor 104 and the p-type transistor 106 includes two finger sub-devices which share a dielectric barrier extending between the respective finger sub-devices. For example, in the semiconductor architecture 100C (of FIG. 1C) the first finger sub-device 108A and the second finger sub-device 108B of the n-type transistor 104 includes the dielectric barrier 120 which extends down one side only of the stacked semiconductors 110 of the first finger sub-device 108A and the second finger sub-device 108B. Similarly, the third finger sub-device 108C and the fourth finger sub-device 108D of the p-type transistor 106 includes the dielectric barrier 120 which extends down one side only of the stacked semiconductors 110 of the third finger sub-device 108C and the fourth finger sub-device 108D. In this way, the dielectric barrier 120 extends between the respective finger sub-devices, such as between the first finger sub-device 108A and the second finger sub-device 108B, and between the third finger sub-device 108C and the fourth finger sub-device 108D, but not at the separation of the n-type transistor 104 and the p-type transistor 106. In the semiconductor architecture 100C, gate extension exists for the first finger sub-device 108A of the n-type transistor 104 and the fourth finger sub-device 108D of the p-type transistor 106.

In accordance with an embodiment, each of the n-type transistor 104 and the p-type transistor 106 includes a total of two finger sub-devices. For example, in the semiconductor architecture 100A (of FIG. 1A), the n-type transistor 104 includes the two finger sub-devices, namely, the first finger sub-device 108A and the second finger sub-device 108B. Similarly, the p-type transistor 106 includes the two finger sub-devices, namely, the third finger sub-device 108C and the fourth finger sub-device 108D.

In accordance with an embodiment, each of the finger sub-devices includes a total of three stacked semiconductors 110. In the semiconductor architecture 100A, each of the finger sub-devices such as the first finger sub-device 108A, the second finger sub-device 108B, the third finger sub-device 108C and the fourth finger sub-device 108D includes the total of three stacked semiconductors (i.e., the plurality of stacked semiconductors 110).

In accordance with an embodiment, depositing the one or more metal gate layers includes depositing the n-type metal gate layer 104A, etching the n-type metal gate layer 104A, and depositing the p-type metal gate layer 106A. The method 200 further comprises deposition of the one or more metal gate layers which starts from the deposition of the n-type metal gate layer 104A all over the substrate 102. Thereafter, the n-type metal gate layer 104A is etched from a certain portion of the substrate 102. Thereafter, on the etched side of the substrate 102 the p-type metal gate layer 106A is deposited. As a result, the two metal gate layers are formed on the substrate 102, such as the n-type metal gate layer 104A and the p-type metal gate layer 106A. Further, the n-type metal gate layer 104A and the p-type metal gate layer 106A are used to connect the plurality of finger sub-devices 108.

Thus, the method 200 for manufacturing the semiconductor architecture 100A with the fork stack device (or multi-finger architecture) which is beneficial for high-current devices and power-performance trade-off devices. Moreover, due to the dielectric barrier 112, each fork stack device of the semiconductor architecture 100A reduces an effective parasitic capacitance (Ceff) and provides a better resistance-capacitance (R-C) trade-off. The gate dielectric layer 116 and the n-type metal gate layer 104A and the p-type metal gate layer 106A of the semiconductor architecture 100A are also beneficial in order to connect each fork stack device, such as the second finger sub-device 108B and the third finger sub-device 108C. This further results into high current and beneficially, the semiconductor architecture 100A may be used in manufacturing high current devices in certain paths in a circuit. Besides, the stacked semiconductors 110 enables the semiconductor architecture 100A to have a compact size as well. Additionally, the method 200 may be used for manufacturing multi-multi finger nanosheet devices.

The steps 202 to 210 are only illustrative and other alternatives can also be provided where one or more steps are added, one or more steps are removed, or one or more steps are provided in a different sequence without departing from the scope of the claims herein.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural. The word “exemplary” is used herein to mean “serving as an example, instance or illustration”. Any embodiment described as “exemplary” is not necessarily to be construed as preferred or advantageous over other embodiments or to exclude the incorporation of features from other embodiments. The word “optionally” is used herein to mean “is provided in some embodiments and not provided in other embodiments”. It is appreciated that certain features of the present disclosure, which are, for clarity, described in the context of separate embodiments, may also be provided in combination in a single embodiment. Conversely, various features of the disclosure, which are, for brevity, described in the context of a single embodiment, may also be provided separately or in any suitable combination or as suitable in any other described embodiment of the disclosure.

1. A semiconductor architecture comprising:
a substrate; and
an n-type transistor and a p-type transistor, wherein each of the n-type transistor and the p-type transistor are formed on the substrate;
wherein each of the n-type transistor and the p-type transistor comprises a plurality of finger sub-devices,
wherein each finger sub-device of the plurality of finger sub-devices comprises a plurality of stacked semiconductors,
wherein one or more of the finger sub-devices of the plurality of finger sub-devices for each of the n-type transistor and the p-type transistor is formed as a fork stack device comprising a dielectric barrier which extends down only one side only of the stacked semiconductors.

2. The semiconductor architecture of claim 1, wherein three sides of each fork stack device are surrounded by a gate dielectric layer and an n-type metal gate layer or a p-type metal gate layer.

3. The semiconductor architecture of claim 2, wherein each of the finger sub-devices of the plurality of finger sub-devices which are not formed as fork stack devices are formed as gate-all-around devices, and wherein all four sides of each fork stack device are surrounded by the gate dielectric layer and the n-type metal gate layer or the p-type metal gate layer.

4. The semiconductor architecture of claim 1, wherein a finger sub-device of the n-type transistor and a finger sub-device of the p-type transistor share the dielectric barrier which extends between the n-type transistor and the p-type transistor.

5. The semiconductor architecture of claim 1, wherein a finger sub-device of the n-type transistor which is distal from the p-type transistor comprises a second dielectric barrier extending down a side of the stacked semiconductors which is distal from the p-type transistor; and
a finger sub-device of the p-type transistor which is distal from the n-type transistor comprises a third dielectric barrier extending down a side of the stacked semiconductors which is distal from the n-type transistor.

6. The semiconductor architecture of claim 1, wherein each of the n-type transistor and the p-type transistor comprises two finger sub-devices which share a second dielectric barrier extending between the respective finger sub-devices.

7. The semiconductor architecture of claim 1, wherein each of the n-type transistor and the p-type transistor comprises a total of two finger sub-devices.

8. The semiconductor architecture of claim 1, wherein each of the finger sub-devices of the plurality finger sub-devices includes a total of three stacked semiconductors.

9. The semiconductor architecture of claim 1, manufactured through a process of:
providing a substrate;
forming a plurality of stacked semiconductors on the substrate;
depositing a gate dielectric layer;
etching a top and at least one side of each finger sub-device of the plurality of finger sub-devices, leaving the dielectric barrier; and
depositing one or more metal gate layers.

10. The semiconductor architecture of claim 9, wherein depositing the one or more metal gate layers comprises depositing an n-type metal gate layer, etching the n-type metal gate layer, and depositing a p-type metal gate layer.

11. A method of manufacturing a semiconductor architecture, the method comprising:
providing a substrate;
forming a plurality of stacked semiconductors on the substrate to form an n-type transistor and a p-type transistor on the substrate, wherein each of the n-type transistor and the p-type transistor comprises a plurality of finger sub-devices, and each finger sub-device of the plurality of finger sub-devices comprises a plurality of stacked semiconductors;
depositing a gate dielectric layer;
etching a top and at least one side of each finger sub-device of the plurality of finger sub-devices, leaving a dielectric barrier which extends down only one side of the stacked semiconductors; and
depositing one or more metal gate layers, wherein one or more of the finger sub-devices of the plurality of finger sub-devices for each of the n-type transistor and the p-type transistor is formed as a fork stack device comprising the dielectric barrier extending down only one side of the stacked semiconductors.

12. The method of claim 11, wherein the etching and depositing steps are configured to surround three sides of each fork stack device with a gate dielectric layer and an n-type metal gate layer or a p-type metal gate layer.

13. The method of claim 11, wherein the etching and depositing steps are configured to form the finger sub-devices which are not formed as fork stack devices as gate-all-around devices, wherein all four sides are surrounded by the gate dielectric layer and the n-type metal gate layer or the p-type metal gate layer.

14. The method of claim 11, wherein the etching of a finger sub-device of the n-type transistor and a finger sub-device of the p-type transistor forms the dielectric barrier which extends between the n-type transistor and the p-type transistor.

15. The method of claim 11, wherein the etching of a finger sub-device of the n-type transistor which is distal from the p-type transistor forms a second dielectric barrier extending down a side of the stacked semiconductors which is distal from the p-type transistor; and
the etching of a finger sub-device of the p-type transistor which is distal from the n-type transistor forms a third dielectric barrier extending down a side of the stacked semiconductors which is distal from the n-type transistor.

16. The method of claim 11, wherein each of the n-type transistor and the p-type transistor comprises two finger sub-devices which share a second dielectric barrier extending between the respective finger sub-devices.

17. The method of claim 11, wherein each of the n-type transistor and the p-type transistor comprise a total of two finger sub-devices.

18. The method of claim 11, wherein each of the finger sub-devices of the plurality of finger sub-devices includes a total of three stacked semiconductors.

19. The method of claim 11, wherein depositing the one or more metal gate layers comprises depositing an n-type metal gate layer, etching the n-type metal gate layer, and depositing a p-type metal gate layer.
